(19) United States
(12) Patent Application Publication
(10) Pub. No.: US 2018/0190662 A1
(43) Pub. Date: Jul. 5, 2018

(54) BIT LINE GATE STRUCTURE OF DYNAMIC RANDOM ACCESS MEMORY (DRAM) AND FORMING METHOD THEREOF

(71) Applicants: UNITED MICROELECTRONICS CORP., Hsin-Chu City (TW); Fujian Jinhua Integrated Circuit Co., Ltd., Quanzhou City (CN)

(72) Inventors: Tzu-Chin Wu, Chiayi County (TW); Wei-Hsin Liu, Changhua County (TW); Yi-Wei Chen, Taichung City (TW); Mei-Ling Chen, Kaohsiung City (TW); Chia-Lung Chang, Tainan City (TW); Ching-Hsiang Chang, Tainan City (TW); Jui-Min Lee, Taichung City (TW); Tsun-Min Cheng, Changhua County (TW); Lin-Chen Lu, Kaohsiung City (TW); Shih-Fang Tzou, Tainan City (TW); Kai-Jiun Chang, Taoyuan City (TW); Chih-Chieh Tsai, Kaohsiung City (TW); Tzu-Chieh Chen, Pingtung County (TW); Chia-Chen Wu, Nantou County (TW)

(21) Appl. No.: 15/854,825

(22) Filed: Dec. 27, 2017

(30) Foreign Application Priority Data
Dec. 29, 2016 (CN) 201611246141.7

(51) Int. Cl. H01L 27/108; H01L 21/033; H01L 23/532; H01L 23/528; H01L 21/768; H01L 21/285

(52) U.S. Cl. CPC H01L 27/10885; H01L 21/0337; H01L 23/53266; H01L 21/0332; H01L 21/28568; H01L 23/53271; H01L 21/76846; H01L 21/76877; H01L 23/528

(57) ABSTRACT

A method of forming a bit line gate structure of a dynamic random access memory (DRAM) includes the following. A hard mask layer is formed on a metal stack by a chemical vapor deposition process importing nitrogen (N₂) gases and then importing amonia (NH₃) gases. The present invention also provides a bit line gate structure of a dynamic random access memory (DRAM) including a metal stack and a hard mask. The metal stack includes a polysilicon layer, a titanium layer, a titanium nitride layer, a first tungsten nitride layer, a tungsten layer and a second tungsten nitride layer stacked from bottom to top. The hard mask is disposed on the metal stack.

### BACKGROUND OF THE INVENTION

### 1. Field of the Invention

The present invention relates generally to a bit line gate structure of a dynamic random access memory (dram) and forming method thereof, and more specifically to a bit line gate structure of a dynamic random access memory (dram) and a forming method of importing nitrogen (N₂) gases and amonia (NH₃) gases sequentially to form a hard mask layer thereof.

### 2. Description of the Prior Art

Random access memory (RAM) can be operated to read data from it and write data into it. As computers containing RAM turn off, data disappears from the RAM immediately. Since data in RAM can be altered easily, RAM is widely used as temporary data storage memory in personal computers. RAM can be classified into dynamic-type and static-type.

A static random access memory (SRAM: Static RAM) stores one-bit data by six transistors, and electricity is not needed during operating to keep this data, thus called Static RAM. Static RAM is a complex structure, therefore having high access speed and high cost, thereby it is often used as a memory providing low capacity but high speed such as a 256 KB or 512 KB cache memory built-in a central processing unit (CPU) of a personal computer.

A dynamic random access memory (DRAM: Dynamic RAM) stores one-bit data by one transistor paired with one capacitor, and electricity must be supported during operating to keep this data, thus called Dynamic RAM. Dynamic RAM is a simple structure, therefore having slow access speed and low cost. Thus, it is often used as a memory providing high capacity but low speed such as a main memory of a personal computer.

Since a CPU mainly affects data calculating and processing speed of a computer while a main memory mainly affects data storage capacity, a cache memory is utilized to save often-used data, thereby the CPU can more quickly reach this often-used data stored in the cache memory, without reaching it in the main memory.

### SUMMARY OF THE INVENTION

The present invention provides a bit line gate structure of a dynamic random access memory (DRAM) and forming method thereof, which forms a hard mask layer by a chemical vapor deposition process importing nitrogen (N₂) gases and then importing amonia (NH₃) gases, thereby reducing the nitridation of a metal layer below the hard mask layer, hence reducing the resistance between the metal layer and the hard mask layer.

The present invention provides a method of forming a bit line gate structure of a dynamic random access memory (DRAM) including the following. A hard mask layer is formed on a metal stack by a chemical vapor deposition process importing nitrogen (N₂) gases and then importing amonia (NH₃) gases.

The present invention provides a bit line gate structure of a dynamic random access memory (DRAM) including a metal stack and a hard mask. The metal stack includes a polysilicon layer, a titanium layer, a titanium nitride layer, a first tungsten nitride layer, a tungsten layer and a second tungsten nitride layer stacked from bottom to top. The hard mask is disposed on the metal stack.

According to the above, the present invention provides a bit line gate structure of a dynamic random access memory (DRAM) and forming method thereof, which forms a hard mask layer by a chemical vapor deposition process importing nitrogen (N₂) gases and then importing amonia (NH₃) gases, thereby reducing the nitridation of a metal layer below the hard mask layer, and thus decreasing the thickness and the nitrogen ratio of a second tungsten nitride layer formed by the nitridation of the metal layer. Hence, this reduces the resistance between the metal layer and the hard mask layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 schematically depicts cross-sectional views of a method of forming a bit line gate structure of a dynamic random access memory (DRAM) according to an embodiment of the present invention.

FIG. 5 schematically depicts a diagram of the nitrogen ratio versus the resistivity of a tungsten nitride layer in a dynamic random access memory (DRAM) according to an embodiment of the present invention.

### DETAILED DESCRIPTION

FIGS. 1-4 schematically depicts cross-sectional views of a method of forming a bit line gate structure of a dynamic random access memory (DRAM) according to an embodiment of the present invention, wherein the cross-sectional views of FIGS. 1-3 are orthogonal to the cross-sectional view of FIG. 4. As FIGS. 1-3 are the cross-sectional views at x-direction, FIG. 4 is the cross-sectional view at y-direction along line BB′.

As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. For clarifying the present invention, FIGS. 1-4 only depicts a memory area A of the substrate 110, but it is not limited thereto. The memory area A may be connected to other areas such as a logical area (not shown), wherein the memory area A may be used for forming a dynamic random access memory (DRAM) therein while the logical area (not shown) may be used for forming active elements such as metal-oxide-semiconductor transistors. At least a shallow trench isolation (STI) structure may be disposed in the substrate 110 between the memory area A and the logical area for isolating elements in the memory area A from elements in the logical area.

A plurality of buried gate structures G are disposed in the substrate 110 of the memory area A. Isolation materials such as a plurality of silicon oxide layers 2, silicon nitride layers 4 and silicon oxide layers 6 or etc may cover the substrate 110 of the memory area A.

A bit line gate structure L is formed on the substrate 110, wherein the bit line gate structure L is preferably disposed on the substrate 110 of the memory area A and covers the plurality of buried gate structures G buried in the substrate 110. Methods of forming the bit line gate structure L may include stacking a plurality of material layers on the substrate 110 blanketly, wherein the material layers may include an amorphous silicon layer 120 and a metal stack M stacked from bottom to top, but it is not limited thereto. The metal stack M may include a titanium layer 132, a titanium nitride layer 134, a first tungsten nitride layer 136 and a tungsten layer 138 stacked from bottom to top. The metal stack M may optionally include a tungsten silicon layer 137 between the titanium nitride layer 134 and the first tungsten nitride layer 136.

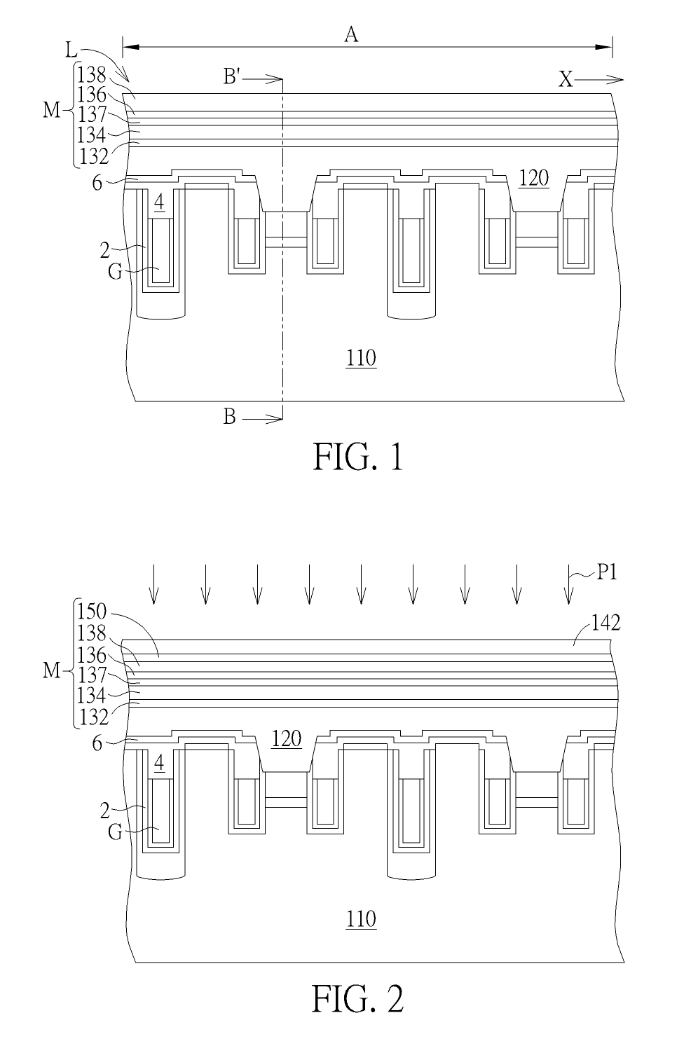

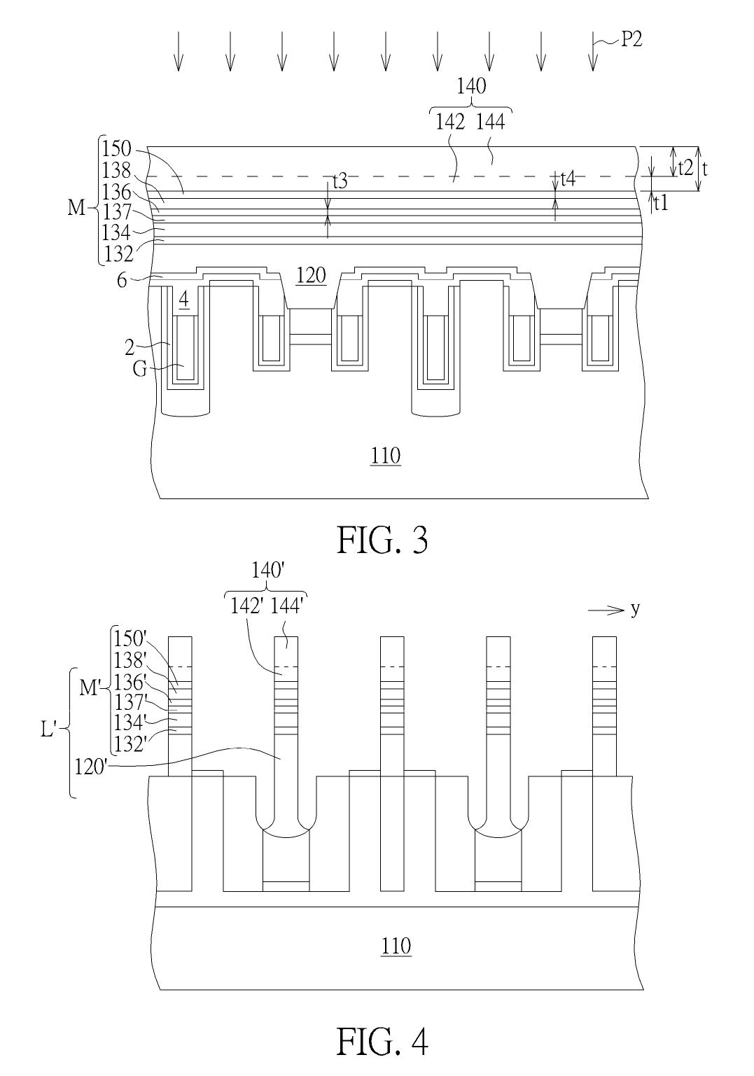

Please refer to FIGS. 2-3, a hard mask layer 140 is formed on the metal stack M. In this embodiment, the hard mask layer 140 is a nitride layer, but it is not limited thereto. By applying the method of the present invention, the hard mask layer 140 is formed by a chemical vapor deposition (CVD) process, wherein the chemical vapor deposition (CVD) process is performed by importing different gases sequentially for forming the hard mask layer 140 and avoiding the pollution of the metal stack M below the hard mask layer 140 at the same time. More precisely, the hard mask layer 140 may include a first nitride layer 142 and a second nitride layer 144 from bottom to top. As shown in FIG. 2, the first nitride layer 142 is formed by a chemical vapor deposition process P1 having nitrogen (N₂) gases imported. In this case, the first nitride layer 142 is formed by the chemical vapor deposition process P1 having nitrogen (N₂) gases imported. In another embodiment, the first nitride layer 142 may be formed by a chemical vapor deposition process having other inert gases imported. As shown in FIG. 3, the second nitride layer 144 is then formed by a chemical vapor deposition process P2 having amonia (NH₃) gases imported. In a preferred embodiment, the first nitride layer 142 and the second nitride layer 144 are formed in-situ, to improve processing efficiency and to prevent the first nitride layer 142 from being polluted. For instance, the chemical vapor deposition process P1 and the chemical vapor deposition process P2 may be performed at one same chamber to form the first nitride layer 142 and the second nitride layer 144, but it is not limited thereto.

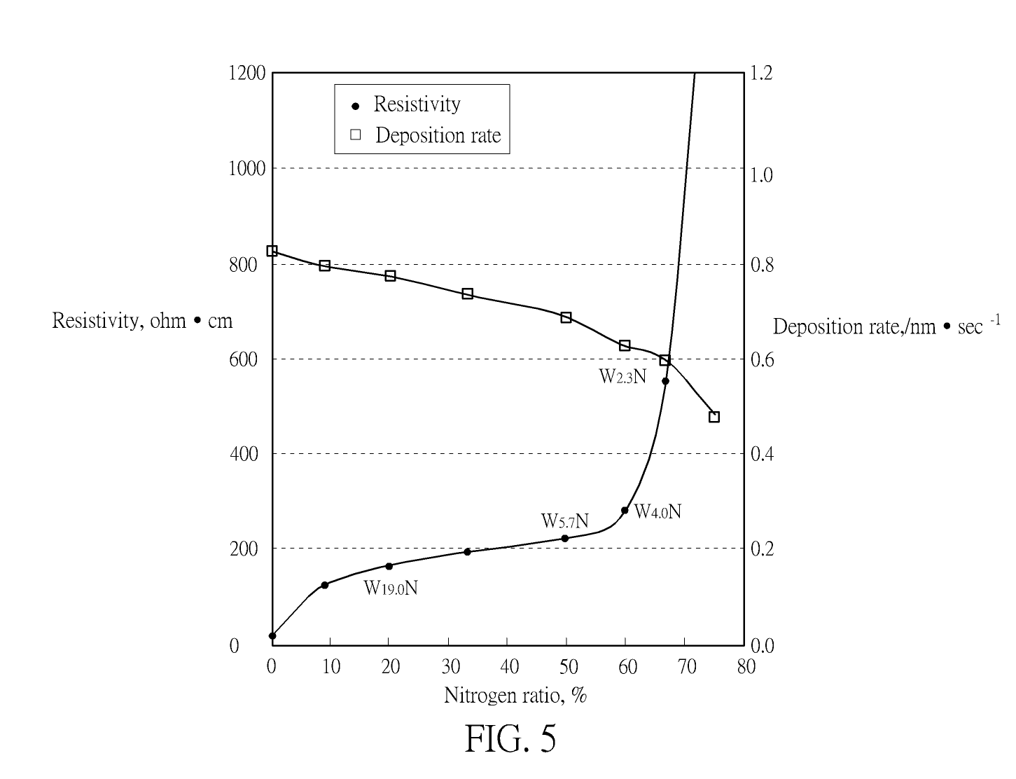

As the chemical vapor deposition process P1 is performed to form the first nitride layer 142, a second tungsten nitride layer 150 is also formed by nitridizing a surface of the tungsten layer 138, as shown in FIG. 2. As the chemical vapor deposition process P2 is performed to form the second nitride layer 144, the metal stack M can be prevented from being nitridized due to the first nitride layer 142. Compared to forming the first nitride layer by a chemical vapor deposition process having larger active gases such as amonia (NH₃) gases imported, forming the first nitride layer 142 by the chemical vapor deposition process P1 having nitrogen (N₂) gas imported can reduce the nitridation of the metal stack M, especially for reducing the tungsten layer 138 at the top of the metal stack M, below the first nitride layer 142. In other words, the thickness of the second tungsten nitride layer 150 formed by nitridizing the tungsten layer 138 and the nitrogen ratio of the second tungsten nitride layer 150 can be decreased, thereby the resistance between the metal stack M and the hard mask layer 140 can be reduced. As shown in FIG. 5, as the nitrogen ratio of the second tungsten nitride layer 150 is larger, the resistivity between the metal stack M and the hard mask layer 140 is larger. As the nitrogen ratio of the second tungsten nitride layer 150 is larger than 50%, the resistivity would increase dramatically. Thus, the nitrogen ratio of the second tungsten nitride layer 150 is less than 50%. The nitrogen ratio of the second tungsten nitride layer 150 is larger than the nitrogen ratio of the first tungsten nitride layer 136, but a thickness t3 of the first tungsten nitride layer 136 is larger than a thickness t4 of the second tungsten nitride layer 150, but it is not limited thereto.

Since the first nitride layer 142 is formed slowly by performing the chemical vapor deposition process P1 having nitrogen (N₂) gases imported, the second nitride layer 144 is formed by the chemical vapor deposition process P2 having amonia (NH₃) gas imported instead to increase the deposition rate. Due to the metal stack M being nitridized by performing the chemical vapor deposition process P2 more than by performing the chemical vapor deposition process P1, the first nitride layer 142 having an enough thickness for preventing the second tungsten nitride layer 150 from being nitridized while the second nitride layer 144 is formed is required. Preferably, a thickness t1 of the first nitride layer 142 is 10% of a thickness t of the hard mask layer 140, and a thickness t2 of the second nitride layer 144 is 90% of the thickness t of the hard mask layer 140. In this way, not only the processing efficiency but also the structure quality can be maintained.

A pattern transferring process is performed such as a patterned photoresist (not shown) may be applied to remove a part of the bit line gate structure L, thereby a bit line gate structure L′ being formed, as shown in FIG. 4. The bit line gate structure L′ may include an amorphous silicon layer 120′ and a metal stack M′, wherein the metal stack M′ may include a titanium layer 132′, a titanium nitride layer 134′, a first tungsten nitride layer 136′ and a tungsten layer 138′ stacked from bottom to top. The metal stack M′ may optionally include a tungsten silicon layer 137′ between the titanium nitride layer 134′ and the first tungsten nitride layer 136′. A hard mask layer 140′ is stacked on the metal stack M′, and the hard mask layer 140′ may include a first nitride layer 142′ and a second nitride layer 144′.

To summarize, the present invention provides a bit line gate structure of a dynamic random access memory (DRAM) and forming method thereof, which forms a hard mask layer by a chemical vapor deposition process importing nitrogen (N₂) gases and then importing amonia (NH₃) gases, thereby reducing the nitridation of a metal layer below the hard mask layer. Hence, this reduces the resistance between the metal layer and the hard mask layer. Preferably, the hard mask layer may be a nitride layer, and methods of forming the hard mask layer may include forming a first nitride layer by performing a chemical vapor deposition process having nitrogen (N₂) gases imported, and then forming a second nitride layer by performing a chemical vapor deposition process having amonia (NH₃) gases imported. The first nitride layer formed by the chemical vapor deposition process having nitrogen (N₂) gases or other inert gases imported can reduce the nitridation of the metal stack below the first nitride layer. This means a thickness of a second tungsten nitride layer formed at the surface of the tungsten layer being the top layer of the metal stack can be reduced, the nitrogen ratio of the second tungsten nitride layer is reduced, and the resistance is therefore reduced. Preferably, the nitrogen ratio of the second tungsten nitride layer is less than 50%.

Furthermore, the chemical vapor deposition process having nitrogen (N₂) gases imported and the chemical vapor deposition process having amonia (NH₃) gases imported are preferably performed in-situ to improve processing efficiency and avoid pollution. A thickness of the first nitride layer is preferably 10% of a thickness of the nitride layer while a thickness of the second nitride layer is preferably 90% of a thickness of the nitride layer to keep the processing efficiency and the structure quality.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a bit line gate structure of a dynamic random access memory (DRAM), comprising:
forming a hard mask layer on a metal stack by a chemical vapor deposition process importing nitrogen (N₂) gases and then importing amonia (NH₃) gases.

2. The method of forming a bit line gate structure of a dynamic random access memory according to claim 1, wherein the metal stack comprises a titanium layer, a titanium nitride layer, a first tungsten nitride layer and a tungsten layer stacked from bottom to top.

3. The method of forming a bit line gate structure of a dynamic random access memory according to claim 2, wherein the metal stack comprises a tungsten silicon layer between the titanium nitride layer and the first tungsten nitride layer.

4. The method of forming a bit line gate structure of a dynamic random access memory according to claim 1, wherein the hard mask layer comprises a nitride layer.

5. The method of forming a bit line gate structure of a dynamic random access memory according to claim 4, wherein the nitride layer has a first nitride layer and a second nitride layer stacked from bottom to top.

6. The method of forming a bit line gate structure of a dynamic random access memory according to claim 5, wherein the first nitride layer is formed by a chemical vapor deposition process importing nitrogen (N₂) gases while the second nitride layer is formed by a chemical vapor deposition process importing amonia (NH₃) gases.

7. The method of forming a bit line gate structure of a dynamic random access memory according to claim 6, wherein firs nitride layer and the second nitride layer are formed in-situ.

8. The method of forming a bit line gate structure of a dynamic random access memory according to claim 5, wherein a thickness of the first nitride layer is 10% of a thickness of the nitride layer, and a thickness of the second nitride layer is 90% of the thickness of the nitride layer.

9. The method of forming a bit line gate structure of a dynamic random access memory according to claim 2, further comprising:
forming a second tungsten nitride layer while the chemical vapor deposition process is performed.

10. The method of forming a bit line gate structure of a dynamic random access memory according to claim 9, wherein the second tungsten nitride layer has a nitrogen ratio less than 50%.

11. The method of forming a bit line gate structure of a dynamic random access memory according to claim 9, wherein a nitrogen ratio of the second tungsten nitride layer is larger than a nitrogen ratio of the first tungsten nitride layer.

12. The method of forming a bit line gate structure of a dynamic random access memory according to claim 9, wherein a thickness of the first tungsten nitride layer is larger than a thickness of the second tungsten nitride layer.

13. A bit line gate structure of a dynamic random access memory (DRAM), comprising:
a metal stack comprising a polysilicon layer, a titanium layer, a titanium nitride layer, a first tungsten nitride layer, a tungsten layer and a second tungsten nitride layer stacked from bottom to top; and
a hard mask disposed on the metal stack.

14. The bit line gate structure of a dynamic random access memory according to claim 13, wherein a thickness of the first tungsten nitride layer is larger than a thickness of the second tungsten nitride layer.

15. The bit line gate structure of a dynamic random access memory according to claim 13, wherein a nitrogen ratio of the second tungsten nitride layer is larger than a nitrogen ratio of the first tungsten nitride layer.

16. The bit line gate structure of a dynamic random access memory according to claim 13, wherein the second tungsten nitride layer has a nitrogen ratio less than 50%.

17. The bit line gate structure of a dynamic random access memory according to claim 13, wherein the metal stack comprises a tungsten silicon layer between the titanium nitride layer and the first tungsten nitride layer.

18. The bit line gate structure of a dynamic random access memory according to claim 13, wherein the hard mask layer comprises a nitride layer.

19. The bit line gate structure of a dynamic random access memory according to claim 18, wherein the nitride layer has a first nitride layer and a second nitride layer stacked from bottom to top.

20. The bit line gate structure of a dynamic random access memory according to claim 19, wherein a thickness of the first nitride layer is 10% of a thickness of the nitride layer, and a thickness of the second nitride layer is 90% of the thickness of the nitride layer.
